(19) United States
(12) Patent Application Publication
(10) Pub. No.: US 2016/0268408 A1
(43) Pub. Date: Sep. 15, 2016

(54) SEMICONDUCTOR DEVICE

(71) Applicant: KABUSHIKI KAISHA TOSHIBA, Tokyo (JP)

(72) Inventors: Kohei OASA, Nonoichi Ishikawa (JP); Yoshiharu TAKADA, Nonoichi Ishikawa (JP); Akira YOSHIOKA, Nomi Ishikawa (JP); Yasuhiro ISOBE, Kanazawa Ishikawa (JP); Hung HUNG, Nonoichi Ishikawa (JP)

(21) Appl. No.: 14/840,692

(22) Filed: Aug. 31, 2015

(30) Foreign Application Priority Data
Mar. 9, 2015 (JP) 2015-045976

(51) Int. Cl. H01L 29/778; H01L 29/205; H01L 29/66; H01L 29/423; H01L 29/10; H01L 29/40; H01L 29/20; H01L 29/207

(52) U.S. Cl. CPC H01L 29/7787; H01L 29/2003; H01L 29/205; H01L 29/207; H01L 29/42372; H01L 29/1033; H01L 29/402; H01L 29/66462

(57) ABSTRACT

A semiconductor device includes a first compound semiconductor layer on a substrate, a second compound semiconductor layer on the first compound semiconductor layer which has a band gap greater than the band gap of the first compound semiconductor layer, and a gate electrode on the second compound semiconductor layer. The gate length of the gate electrode is more twice as great as the thickness of the first compound semiconductor layer, and is equal to or smaller than five times as great as the thickness of the first compound semiconductor layer.

### CROSS-REFERENCE TO RELATED APPLICATION

This application is based upon and claims the benefit of priority from Japanese Patent Application No. 2015-045976, filed Mar. 9, 2015, the entire contents of which are incorporated herein by reference.

### FIELD

An embodiment described herein relates generally to a semiconductor device, and particularly, to a semiconductor device that uses a compound semiconductor.

### BACKGROUND

An electronic device that uses a nitride semiconductor is used for a high-speed electronic device or a power semiconductor device. In addition, a semiconductor light emitting diode (LED) of a nitride semiconductor is used for a display device, illumination, or the like.

A power semiconductor device requires a high breakdown voltage and a low on-resistance. There is a trade-off relationship, based on the semiconductor element material, between breakdown voltage and on-resistance, but when a wide band gap semiconductor, such as a nitride semiconductor or silicon carbide (SiC) is used as an element material, the trade-off relationship based on the semiconductor material may be improved, compared to silicon, and a high breakdown voltage and a low on-resistance may be achieved. In addition, an element that employs a nitride semiconductor, such as GaN or AlGaN has excellent material properties, from which a high-performance power semiconductor device may be formed.

### DESCRIPTION OF THE DRAWINGS

FIG. 1 is a schematic cross section of a semiconductor device according to an embodiment.

FIG. 2 is a diagram illustrating conditions of a gate electrode and a channel layer according to the embodiment.

FIG. 3 is a graph representing a relationship between gate voltage and drain current for different gate lengths.

### DETAILED DESCRIPTION

An embodiment provides a semiconductor device capable of reduced current collapse phenomena and reduced leakage current.

In general, according to one embodiment, a semiconductor device includes a first compound semiconductor layer on a substrate, a second compound semiconductor layer having a band gap greater than the band gap of the first compound semiconductor layer, on the first compound semiconductor layer, and a gate electrode on the second compound semiconductor layer. The length of the gate electrode is more than twice as great as the thickness of the first compound semiconductor layer, and is equal to or smaller than five times as great as the thickness of the first compound semiconductor layer.

Hereinafter, an embodiment will be described with reference to the drawings. However, the drawings are schematic and conceptual, and dimensions, proportions, or the like of the respective drawings are not necessarily those of an actual device. The embodiment described below exemplifies a device and a method in which a technical concept of the invention is embodied, and the technical concept of the invention is not limited by shapes, structures, and arrangement of configuration components, or the like. In the following description, the same symbols or reference numerals will be attached to the elements having the same functions and configurations, and repeated thereof description will be made only when necessary.

1. Structure of Semiconductor Device

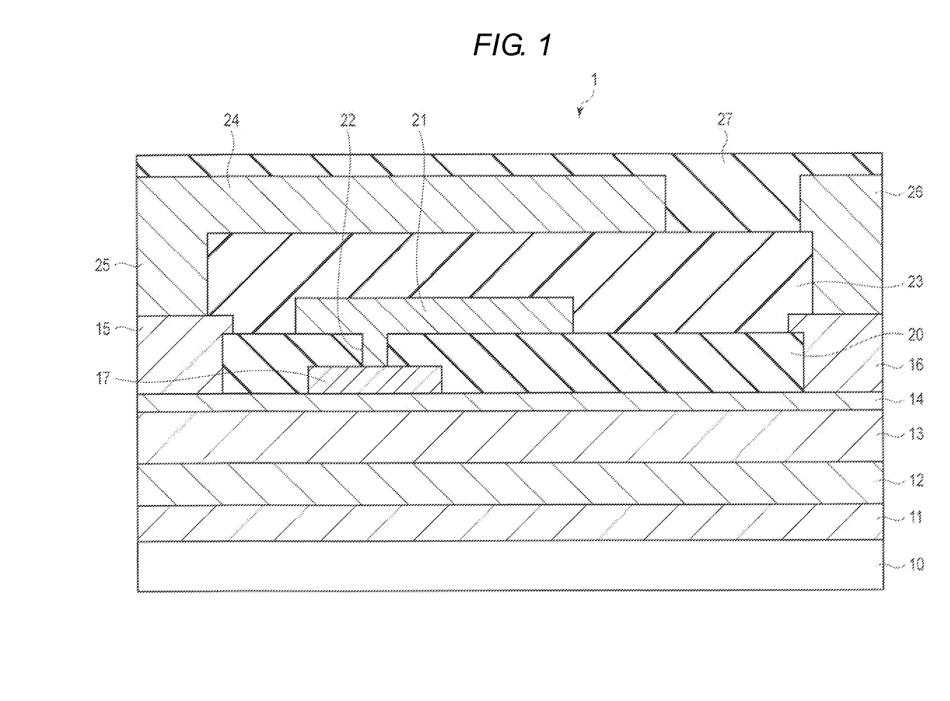

FIG. 1 is a sectional diagram of a semiconductor device 1 according to an embodiment. The semiconductor device 1 according to the present embodiment is configured with a heterojunction field effect transistor (HFET) or a high electron mobility transistor (HEMT).

The semiconductor device 1 includes a buffer layer 11, a high resistance layer 12, a channel layer 13, a barrier layer 14, and various electrodes that are sequentially stacked on a substrate 10.

The substrate 10 is a silicon (Si) substrate in which for example, a (111) plane is used as a main plane. Sapphire (Al₂O₃), silicon carbon (SiC), gallium phosphide (GaP), indium phosphide (InP), gallium arsenide (GaAs), or the like may be used for the substrate 10. In addition, a substrate including an insulation layer may also be used for the substrate 10. For example, a silicon on insulator (SOI) substrate may be used for the substrate 10. The substrate 10 may be a single crystal substrate on which an epitaxial layer may be grown, and is not limited to those listed above.

The buffer layer 11 mitigates distortion caused by a difference between the lattice constant of a nitride semiconductor layer that is formed on the buffer layer 11 and the lattice constant of the substrate 10, and has a function of controlling or affecting the crystalline structure of the nitride semiconductor layer that is formed on the buffer layer 11. In addition, the buffer layer 11 has a function of suppressing a chemical reaction between an element (for example, gallium (Ga)) that is contained in the nitride semiconductor layer which is formed on the buffer layer 11 and an element (for example, silicon (Si)) of the substrate 10. The buffer layer 11 is formed of, for example, AlₓGa₁₋ₓN (0≦X≦1). In the present embodiment, the buffer layer 11 is formed of AlN. The buffer layer 11 is not an essential element of the present embodiment, and may be omitted.

The high resistance layer 12 has a function of increasing the breakdown voltage of the semiconductor device 1, and mainly increases a breakdown voltage between a drain electrode and the substrate. That is, by providing the high resistance layer 12, a voltage based on the resistance of the high resistance layer 12 is applied to the high resistance layer 12, whereby the breakdown voltage may be increased by the amount of the voltage. The high resistance layer 12 is configured with a nitride semiconductor layer in which carbon (C) is doped, and the nitride semiconductor layer is formed of, for example, In_{X}Al_{Y}Ga_{(1-X-Y)}N (0≦X<1, 0≦Y<1, 0≦X+Y<1). In the present embodiment, the high resistance layer 12 is formed of GaN (C—GaN) in which carbon is doped. The carbon concentration of the high resistance layer 12 is greater than the carbon concentration of the channel layer 13 which will be described below. The carbon concentration of the high resistance layer 12 is, for example, 1×10¹⁷ cm⁻³ or more. A resistance value of the high resistance layer 12 is appropriately configured in accordance with a breakdown voltage that is desired for the semiconductor device 1. The high resistance layer 12 is not an essential element of the present embodiment, and may be omitted.

The channel layer 13 is a layer in which the channel (current path) of a transistor is formed. The channel layer 13 is formed of In_{X}Al_{Y}Ga_{(1-X-Y)}N (0≦X<1, 0≦Y<1, 0≦X+Y<1). It is preferable that the channel layer 13 is configured with a nitride semiconductor layer with a uniform crystalline structure (high quality), with minimal defects in the lattice and minimal distortion. In the present embodiment, the channel layer 13 is formed of GaN. A more specific configuration of the channel layer 13 will be described below.

The barrier layer 14, with the channel layer 13, configures a heterojunction. The barrier layer 14 is configured with a nitride semiconductor layer having a greater band gap than that of the channel layer 13. The barrier layer 14 is formed of In_{X}Al_{Y}Ga_{(1-X-Y)}N (0≦X<1, 0≦Y<1, 0≦X+Y<1). In the present embodiment, the barrier layer 14 is formed of undoped AlGaN. Herein, “undoped” means that impurities are not intentionally doped into the layer, and for example, an amount of impurities that are inherent in a manufacturing process or the like is included as “undoped”.

In the heterojunction of the channel layer 13 and the barrier layer 14, the barrier layer 14 is smaller in lattice constant than the channel layer 13, whereby distortion occurs in the barrier layer 14. Piezoelectric polarization occurs in the barrier layer 14 by a piezoelectric effect due to this distortion, and a two-dimensional electron gas (2DEG) is generated near an interface between the channel layer 13 and the barrier layer 14. The two-dimensional electron gas forms the channel between a source electrode 15 and a drain electrode 16.

A plurality of semiconductor layers that configure the semiconductor device 1 are sequentially formed using, for example, epitaxial growth that uses a metal organic chemical vapor deposition (MOCVD) method. That is, the plurality of semiconductor layers that configure the semiconductor device 1 are configured as epitaxial layers.

The source electrode 15 and the drain electrode 16 are provided on the barrier layer 14 and spaced from each other. The source electrode 15 and the two-dimensional electron gas are in ohmic contact with each other via the barrier layer 14. In the same manner, the drain electrode 16 and the two-dimensional electron gas are in ohmic contact with each other via the barrier layer 14. That is, both the source electrode 15 and the drain electrode 16 are configured to include materials in ohmic contact with the two-dimensional electron gas 2DEG. Titanium (Ti), a stacked structure of Al/Ti, or the like is used for the source electrode 15 and the drain electrode 16. The right side of “/” denotes a lower layer, and the left side of “/” denotes an upper or overlying layer.

A gate electrode 17 is provided on the barrier layer 14 and between, and spaced from, the source electrode 15 and the drain electrode 16. In order to increase the breakdown voltage between a gate and a drain, a distance between the gate electrode 17 and the drain electrode 16 is longer than the distance between the gate electrode 17 and the source electrode 15. The gate electrode 17 and the barrier layer 14 form a Schottky junction with each other. That is, the gate electrode 17 includes a material that forms a Schottky junction with the barrier layer 14. The semiconductor device 1 illustrated in FIG. 1 is a Schottky barrier type HEMT. Nickel (Ni), a stacked structure of Au/Ni, or the like is used for the gate electrode 17.

Drain current in the device may be controlled by a Schottky barrier that is generated by a junction of the gate electrode 17 and the barrier layer 14. In addition, mobility of carriers that flow in the two-dimensional electron gas is high, whereby the semiconductor device 1 may perform a very fast switching operation.

The semiconductor device 1 is not limited to a Schottky barrier type HEMT, and may be a metal insulator semiconductor (MIS) type HEMT in which a gate insulating film is interposed between the barrier layer 14 and the gate electrode 17. In addition, a junction type gate structure may be applied to the HEMT. The junction type gate structure is configured in such a manner that a p type nitride semiconductor layer (for example, GaN layer) is provided on the barrier layer 14, and the gate electrode 17 is provided on the p type nitride semiconductor layer.

Configuration of Field Plate Electrode

The semiconductor device 1 includes a field plate electrode (gate field plate electrode) that is electrically connected to the gate electrode 17, and a field plate electrode (source field plate electrode) that is electrically connected to the source electrode 15. That is, the semiconductor device 1 includes a so-called double field plate structure.

An interlayer insulating layer 20 is provided on the gate electrode 17 and the barrier layer 14. Silicon oxide (SiO₂), silicon nitride (SiN), a high dielectric (high-k) material, or the like is used for the interlayer insulating layer 20. Hafnium oxide (HfO₂) or the like is used for the high-k material.

A gate field plate electrode 21 is provided on the interlayer insulating layer 20. The gate field plate electrode 21 is electrically connected to the gate electrode 17 via a contact 22. The gate field plate electrode 21 extends toward the drain electrode 16 from top of the gate electrode 17. The end of the gate field plate electrode 21 is positioned between the drain electrode 16 and the gate electrode 17.

An interlayer insulating layer 23 is provided on the gate field plate electrode 21 and the interlayer insulating layer 20. Silicon oxide (SiO₂), silicon nitride (SiN), a high-k material, or the like is used for the interlayer insulating layer 23.

A source field plate electrode 24 is provided over the interlayer insulating layer 23. The source field plate electrode 24 is electrically connected to the source electrode 15 via a contact 25. The source field plate electrode 24 extends toward the drain electrode 16 from the top of the source electrode 15. The end of the source field plate electrode 24 extends to a location closer to the drain electrode 16 than does the gate field plate electrode 21.

An electrode 26 is provided on the drain electrode 16. A protection layer 27 is provided on the interlayer insulating layer 23, the source field plate electrode 24, and the electrode 26. The protection layer 27 is also referred to as a passivation layer. The protection layer 27 is configured with an insulator, and silicon nitride (SiN), silicon oxide (SiO₂), or the like is used for the protection layer 27.

A field plate electrode is not an essential requirement of the present embodiment, and thus, the semiconductor device 1 may not include a field plate electrode. In addition, the semiconductor device 1 may include only one of the gate field plate electrode and the source field plate electrode.

2. Relationship Between Gate Electrode 17 and Channel Layer 13

In an HEMT (also referred to as HFET) that is used as the semiconductor device 1, there is a case in which a leakage current when the device is in the OFF state is increased by threshold voltage variation due to, for example, drain induced barrier lowering (DIBL). In addition, if the gate length is shortened in order to increase operation speed, the influence of a short channel effect (SCE) is increased, and leakage current generated by punch-through increases. The short channel effect is a phenomenon in which, if the gate length of a transistor is shortened, it is difficult to control the passage of carriers through the channel based on gate voltage. Even when an OFF voltage is applied to a gate of transistor, drain current (leakage current) easily flows through the channel by the short channel effect. The gate length (sometimes known as the channel length) is the length of a gate electrode in a direction between a source electrode and a drain electrode.

By doping carbon (C) into the GaN layer that is used as the channel layer 13, the short channel effect may be reduced, and when a transistor is in the OFF state, the control of the drain current that is generated by a gate voltage may be improved. However, the current collapse phenomena will be increased, and in addition, carrier mobility is decreased due to impurities (for example, carbon) which can trap carriers in the channel. If mobility is decreased, the resistance of the channel (2DEG) is increased, and an ON resistance (Ron) is increased.

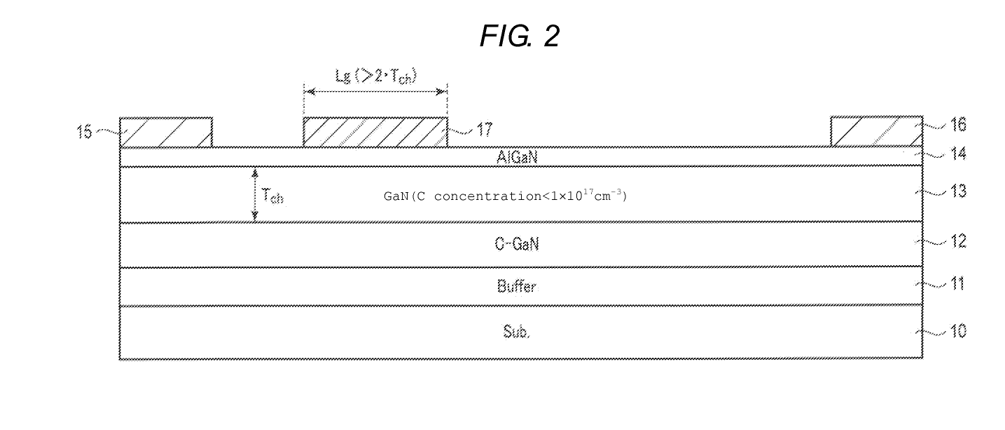

Accordingly, in the present embodiment, the thickness of the channel layer 13 is increased and thereby current collapse is reduced, and a gate length is longer and thereby a short channel effect is reduced. FIG. 2 is diagram illustrating conditions of the gate electrode 17 and the channel layer 13 according to the present embodiment.

In the present embodiment, if the length of the gate electrode 17 is referred to as Lg and the thickness of the channel layer 13 that is configured with a GaN layer is referred to as Tch, a relationship thereof is represented by the following Expression (1).

Lg>2.5×Tch (1)

In addition, if the gate length Lg is lengthened, the OFF characteristic of the transistor is improved, but the travel distance of an electron is lengthened, and thereby, the ON resistance is increased, and as a result, operation speed is decreased. From this viewpoint, in the present embodiment, it is preferable that the gate length Lg is equal to or smaller than five times the thickness Tch of the channel layer 13. In addition, it is preferable that, in order to further increase the operation speed, the gate length Lg is equal to or smaller than three times the thickness Tch of the channel layer 13.

In addition, the channel layer 13 includes carbon (that is, carbon is doped into the channel layer 13), and a carbon concentration of the channel layer 13 is set as a value less than 1×10¹⁷ cm⁻³. By doing this, the decrease of carrier mobility is suppressed and the short channel effect is reduced.

The gate length Lg is set in a sequence of the following i and ii.

i. The thickness Tch of the channel layer 13 and the carbon concentration of the channel layer 13 are determined in such a manner that the desired operation characteristics of the semiconductor device 1 may be achieved and the current collapse phenomena is suppressed.
ii. The gate length Lg is determined using the thickness Tch of the channel layer 13 that is obtained from the section i, and the above Expression (1).

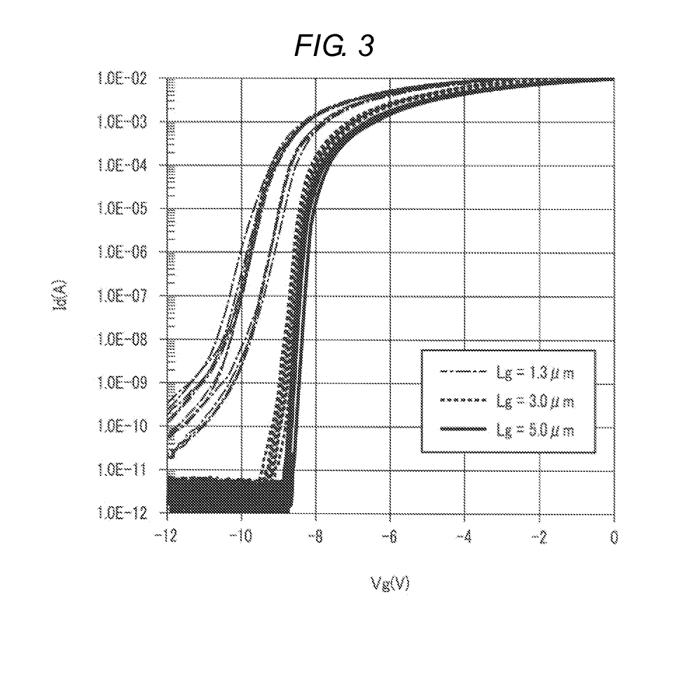

FIG. 3 is a graph representing a relationship between a gate voltage and a drain current, for different gate lengths. A horizontal axis of FIG. 3 denotes a gate voltage Vg (V) that is applied to a gate electrode, and a vertical axis of FIG. 3 denotes a drain current Id (A). In the graph of FIG. 3, the thickness of a channel layer is set as approximately 1.2 μm. FIG. 3 illustrates a graph for three values of gate length (Lg=1.3 μm, 3.0 μm, 5.0 μm).

As may be seen from FIG. 3, if the gate length Lg equals 1.3 μm, a leakage current is generated by the short channel effect. In contrast to this, if the gate length Lg equals 3.0 μm, the control (suppression) of the drain current while a transistor is in the OFF state may be easily performed, and the leakage current may be reduced. In the same manner, even if the gate length Lg equals 5.0 μm, the same suppression of the leakage current as in the case in which the gate length Lg equals 3.0 μm is obtained.

In FIG. 3, if the thickness Tch of the channel layer 13 equals 1.2 μm and the gate length Lg equals 3.0 μm, the above Expression (1) is satisfied. In the same manner, if the thickness Tch of the channel layer 13 equals 1.2 μm and the gate length Lg equals 5.0 μm, the above Expression (1) is satisfied.

3. Effects

As described above, the present embodiment includes the channel layer 13 located on the substrate 10, the barrier layer located on the channel layer 13 which configures a heterojunction with the channel layer 13, and the gate electrode 17 located on the barrier layer 14. The channel layer 13 and the barrier layer 14 are configured with a compound semiconductor layer, for example, a nitride semiconductor layer. Specifically, the channel layer 13 is configured with a GaN layer, and the barrier layer 14 is configured with an AlGaN layer. In addition, in the present embodiment, trade-off of current collapse and the short channel effect is improved by (1) doping carbon as an impurity into the channel layer 13 within a range in which current collapse is not triggered, and (2) configuring the gate length to a required minimum limit. For this purpose, the gate length Lg of the gate electrode 17 is set as a value greater than two and one-half times the thickness of the channel layer 13, and as a value equal to or smaller than five times as great as the thickness of the channel layer 13. In addition, the concentration of carbon in the channel layer 13 is set to a value lower than 1×10¹⁷ cm⁻³.

Thus, according to the present embodiment, the short channel effect may be reduced, and thereby the OFF characteristics of the device are improved, and leakage current is reduced. In addition, by doping carbon into the channel layer 13 at a concentration of 1×10¹⁷ cm⁻³ or less, it is possible to further reduce the short channel effect. Thus, the gate length may be shortened to a required minimum limit, and thereby it is possible to increase operation speed (mobility) and also suppress the current collapse phenomena.

In addition, if the semiconductor device 1 includes a field plate electrode, and as a result the parasitic capacitor that is generated according to the size of a gate electrode is smaller in ratio than a parasitic capacitor of the field plate electrode. For this reason, even if a gate length of a gate electrode is long to a certain extent, the parasitic capacitor that is inherently formed in the semiconductor device 1 is not substantially affected.

The present embodiment configures a semiconductor device using a nitride semiconductor. However, the present embodiment is not limited to this, and may also apply a compound semiconductor other than a nitride semiconductor.

In the present specification, it is assumed that the “nitride semiconductor” includes a semiconductor of all kinds of composition in which composition ratios x and y are changed within a range of each of x and y, in a chemical formula that is InₓAl_{y}Ga_{(1-x-y)}N (0≦x≦1, 0≦y≦1, 0≦x+y≦1). In addition, it is assumed that, in the above chemical formula, a semiconductor which also further contains V-group elements other than N (nitride), a semiconductor which further contains various elements to be contained to control various properties such as a conduction type, and a semiconductor which further contains various elements to be unintentionally contained are contained in the “nitride semiconductor”.

In the present specification, “stack” includes a case in which layers overlap each other with a certain layer interposed therebetween, in addition to a case in which the layers overlap in contact with each other. In addition, “provided or located on something” includes a case in which a certain layer is provided interposed between layers, in addition to a case in which the layer is provided in direct contact with the layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first compound semiconductor layer on a substrate;
a second compound semiconductor layer on the first compound semiconductor layer and having a band gap greater than a band gap of the first compound semiconductor layer; and
a gate electrode on the second compound semiconductor layer,
wherein a gate length of the gate electrode is more than two and one-half times a thickness of the first compound semiconductor layer, and is equal to or less than five times the thickness of the first compound semiconductor layer.

2. The device according to claim 1, wherein
the first compound semiconductor layer contains carbon, and
a carbon concentration of the first compound semiconductor layer is less than 1×10¹⁷ cm⁻³.

3. The device according to claim, wherein
the gate length of the gate electrode is three times or less than the thickness of the first compound semiconductor layer.

4. The device according to claim 1, wherein
the first and second compound semiconductor layers are nitride semiconductor layers.

5. The device according to claim 1, wherein
the first and second compound semiconductor layers comprise gallium nitride.

6. The device according to claim 1, wherein the second compound semiconductor layer comprises AlGaN.

7. The device according to claim 1, wherein the gate electrode forms a Schottky junction with the second compound semiconductor layer.

8. The device according to claim 1, further comprising a gate insulating film interposed between the gate electrode and the second compound semiconductor layer.

9. The semiconductor device according to claim 1, further comprising:
a source electrode located on the second semiconductor layer; and
a drain electrode located on the second semiconductor layer, wherein
the gate electrode is interposed between the source electrode and the drain electrode.

10. The semiconductor device according to claim 9, further comprising:
an insulating layer on the second compound semiconductor layer between the gate electrode and the source electrode and between the drain electrode and the gate electrode; and
a field plate electrode extending from the gate electrode, on the insulating layer, the field plate electrode extending from the gate electrode in the direction of the drain electrode.

11. A method of suppressing leakage current in a compound semiconductor device, comprising:
providing a first compound semiconductor layer;
providing a second compound semiconductor layer having a band gap greater than the band gap of the first compound semiconductor layer over the first compound semiconductor layer;
providing a gate electrode over the second compound semiconductor layer, wherein a gate length thereof is more than two and one-half times a thickness of the first compound semiconductor layer and equal to or less than five times a thickness of the first semiconductor layer.

12. The method of claim 11, wherein the gate length is determined based on a desired first compound semiconductor layer property.

13. The method of claim 11, further comprising:
providing a gate length equal to or less than three times the thickness of the first compound semiconductor layer.

14. The method of claim 11, wherein the compound semiconductor is a nitride semiconductor.

15. The method of claim 14, wherein the first compound semiconductor layer comprises GaN and the second compound semiconductor layer comprises AlGaN.

16. The method of claim 11, further comprising:
providing the first semiconductor layer with a carbon concentration of less than 1×10¹⁷ cm⁻³.

17. The method of claim 11, further comprising:
forming a Schottky junction between the gate electrode and the second compound semiconductor layer.

18. A semiconductor device configured at least in part with a compound semiconductor, comprising
a channel layer having a thickness;
a barrier layer provided over the channel layer, the barrier layer having a band gap greater than a band gap of the channel layer; and
a gate electrode on the barrier layer, wherein a length of the gate electrode is greater than two and one-half times a thickness of the channel layer and less than or equal to five times the thickness of the channel layer.

19. The semiconductor device of claim 18, wherein the channel layer has a carbon concentration of less than 1×10¹⁷ cm⁻³.

20. The semiconductor device of claim 18, wherein the gate electrode forms a Schottky junction with the barrier layer.
